(19) United States
(12) Patent Application Publication
(10) Pub. No.: US 2023/0240004 A1
(43) Pub. Date: Jul. 27, 2023

(54) OPTICALLY REFLECTIVE PCB

(71) Applicant: Panasonic Automotive Systems Company of America, Division of Panasonic Corporation of North America, Peachtree City, GA (US)

(72) Inventors: EDO OMANOVIC, SHELBY TOWNSHIP, MI (US); PATRICK O'CONNELL, NOVI, MI (US)

(21) Appl. No.: 18/101,956

(22) Filed: Jan. 26, 2023

Related U.S. Application Data
(60) Provisional application No. 63/303,336, filed on Jan. 26, 2022.

(51) Int. Cl. H05K 1/02; G02F 1/13357; G02B 27/01; G02F 1/1335; B60K 35/00

(52) U.S. Cl. CPC H05K 1/0274; G02F 1/133605; G02B 27/0101; G02F 1/133607; B60K 35/00; H05K 2201/10136; H05K 2201/2054; H05K 2201/10106; G02F 1/133603; B60K 2370/1529; B60K 2370/23; B60K 2370/332

(57) ABSTRACT

A head up display system presents a virtual image to a human driver of a motor vehicle. A picture generation unit includes a printed circuit board having at least one light emitting device emitting light from a surface of the printed circuit board. The surface has an optically reflective coating. A liquid crystal display receives the emitted light and reflects a portion of the received emitted light back to the printed circuit board. The optically reflective coating of the printed circuit board reflects the light reflected by the liquid crystal display back to the liquid crystal display. At least one mirror reflects light passed by the liquid crystal display toward a windshield of the motor vehicle such that the light is reflected by the windshield and is visible to the human driver as the virtual image.

### CROSS-REFERENCED TO RELATED APPLICATIONS

This application claims benefit of U.S. Provisional Application No. 63/303,336, filed on Jan. 26, 2022, the disclosure of which is hereby incorporated by reference in its entirety for all purposes.

### BACKGROUND OF THE INVENTION

### 1. Field of the Invention

The present invention relates to a head up display (HUD) of a motor vehicle.

### 2. Description of the Related Art

A head up display emits light that reflects from the front windshield to be seen by the driver. The light appears to come from a virtual image in front of the driver and in front of the windshield. This type of head up display is currently commercially available.

Conventional head up displays create the virtual image by first using a display or picture generation unit to create an image. Next, the light from the image is reflected from one or more mirrors. Next, the light from the mirrors is directed up to the windshield and is then reflected from the windshield towards the driver. The mirrors are designed and positioned relative to the display so that the light seen by the driver, which is reflected from the windshield, appears to come from a virtual image that is outside of the vehicle. The mirrors and display are typically contained in a package that occupies a volume beneath the top surface of the dashboard.

A problem with a HUD is that a high level of brightness is required for the driver to be able to see a virtual image. However, an optical system that utilizes an LCD (liquid crystal display) has poor light transmissivity, with more than 90% of the light being lost and less than 10% of the light passing through the LCD layer.

### SUMMARY OF THE INVENTION

The invention may provide an optically reflective PCB (printed circuit board) that improves the efficiency of LEDs (light emitting diodes) in a HUD. The invention may recover as much lost light as possible by taking the light reflected back down the optical system from the LCD and force it back up through the optical system by utilizing a reflective layer on the PCB where light is generated. Currently there is no optically reflective coating placed on PCBs. By adding a reflective layer to the PCB, the present invention may raise reflectivity above 90% and minimize light loss at the PCB.

The invention may enable more light to pass through the LCD layer and provide a brighter virtual image. In another embodiment, the invention may enable the same level of brightness to be achieved by using less power at the LEDs due to increased optical efficiency.

The invention comprises, in one form thereof, a head up display system that presents a virtual image to a human driver of a motor vehicle. A picture generation unit includes a printed circuit board having at least one light emitting device emitting light from a first surface of the printed circuit board. The first surface has an optically reflective coating. A liquid crystal display receives the emitted light and reflects a portion of the received emitted light back to the printed circuit board. The optically reflective coating of the printed circuit board reflects the light reflected by the liquid crystal display back to the liquid crystal display. At least one mirror reflects light passed by the liquid crystal display toward a windshield of the motor vehicle such that the light is reflected by the windshield and is visible to the human driver as the virtual image.

The invention comprises, in another form thereof, a method for presenting a virtual image to a human driver of a motor vehicle, including providing a printed circuit board having a surface with an optically reflective coating. Light is emitted from the surface of the printed circuit board. A liquid crystal display is used to receive the emitted light and reflect a portion of the received emitted light back to the printed circuit board. The optically reflective coating of the printed circuit board is used to reflect the light reflected by the liquid crystal display back to the liquid crystal display. At least one mirror is used to reflect light passed by the liquid crystal display toward a windshield of the motor vehicle such that the light is reflected by the windshield and is visible to the human driver as the virtual image.

The invention comprises, in yet another form thereof, a picture generation unit for a head up display system that presents a virtual image to a human driver of a motor vehicle. The picture generation unit includes a printed circuit board having at least one light emitting device emitting light from a surface of the printed circuit board. The surface has an optically reflective aluminum coating. A liquid crystal display receives the emitted light and reflects a portion of the received emitted light back to the printed circuit board. The optically reflective aluminum coating of the printed circuit board reflects the light reflected by the liquid crystal display back to the liquid crystal display. Light passing through the liquid crystal display is reflected so as to be visible to the human driver as the virtual image.

### BRIEF DESCRIPTION OF THE DRAWINGS

The above-mentioned and other features and objects of this invention, and the manner of attaining them, will become more apparent and the invention itself will be better understood by reference to the following description of embodiments of the invention taken in conjunction with the accompanying drawings, wherein:

FIG. 1 is a schematic side view of one embodiment of a motor vehicle including a HUD arrangement of the present invention.

FIG. 2 is a schematic view of the picture generation unit of the HUD arrangement of FIG. 1.

FIG. 3 is a flow chart of one embodiment of a method of the present invention for presenting a virtual image to a human driver of a motor vehicle.

### DETAILED DESCRIPTION

The embodiments hereinafter disclosed are not intended to be exhaustive or limit the invention to the precise forms disclosed in the following description. Rather the embodiments are chosen and described so that others skilled in the art may utilize its teachings.

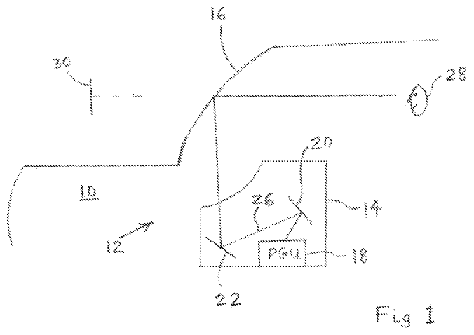

FIG. 1 illustrates one embodiment of a motor vehicle 10 including a head up display (HUD) arrangement 12 of the present invention, including a HUD unit 14 and a windshield 16. HUD unit 14 may include a picture generation unit (PGU) 18, a fold mirror 20, and a second mirror 22.

During use, a light field 26 from PGU 18, after being first reflected by mirror 20, may be reflected by mirror 22 and then by windshield 16 such that the reflection is visible to a driver 28 as a virtual image 30.

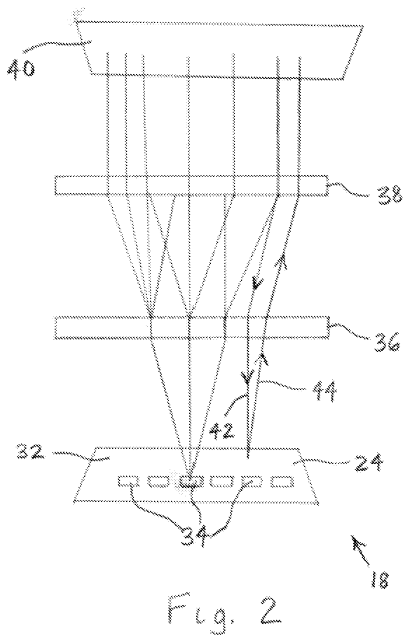

FIG. 2 further illustrates PGU 18 of FIG. 1, including a printed circuit board (PCB) 32 having an optically reflective top coating 24 and a plurality of light emitting diodes 34. PGU 18 further includes a lens 36, a collimating lens 38, and a liquid crystal display (LCD) 40.

During use, LEDs 34 emit light towards lens 36. Lens 36 focuses the received light toward collimating lens 38. Collimating lens 38 collimates the light from lens 36 toward LCD 40. Some of the collimated light received by LCD 40 passes through LCD 40 and some is reflected back to PCB 32, as indicated at 42. The light that passes through LCD 40 is then reflected by mirrors 20, 22 and windshield 16, and is thereby visible to driver 28 as virtual image 30.

Optically reflective coating 24 reflects most of the light reflected by LCD 40 back to LCD 40, as indicated at 44, and some of this light reflected by coating 24 passes through LCD 40. It may be possible for more than 90 percent of the light reflected by LCD 40 to be reflected back to LCD 40 by optically reflective coating 24. The remaining light reflected by LCD 40 (possibly less than 10% of the light reflected by LCD 40) may be lost. Thus, due to reflection of the light by optically reflective coating 24, more light may be transmitted through LCD 40 with the same level of power.

It is to be understood that the drawing of FIG. 2 is simplified as it does not show the amount of light lost. Rather FIG. 2 mainly illustrates the basic function of the invention.

In one embodiment, optically reflective coating 24 is in the form of a layer of aluminum. Because aluminum is electrically conductive, the electronic circuit of PCB 32 may be configured such that the aluminum layer does not create any electrical shorts in PCB 32.

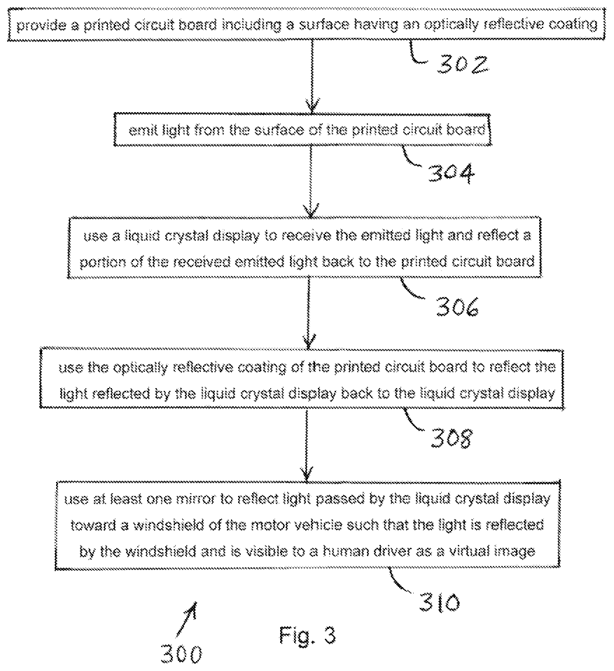

FIG. 3 illustrates one embodiment of a method 300 of the present invention for presenting a virtual image to a human driver of a motor vehicle. In a first step 302, a printed circuit board is provided including a surface having an optically reflective coating. For example, PGU 18 of FIG. 1 includes a printed circuit board (PCB) 32 having an optically reflective top coating 24.

Next, in step 304, light is emitted from the surface of the printed circuit board. For example, printed circuit board (PCB) 32 includes a plurality of light emitting diodes 34 that emit light a light field 26.

In a next step 306, a liquid crystal display is used to receive the emitted light and reflect a portion of the received emitted light back to the printed circuit board. For example, some of the collimated light received by LCD 40 passes through LCD 40 and some is reflected back to PCB 32, as indicated at 42 (FIG. 2).

In step 308, the optically reflective coating of the printed circuit board is used to reflect the light reflected by the liquid crystal display back to the liquid crystal display. For example, optically reflective coating 24 reflects most of the light reflected by LCD 40 back to LCD 40, as indicated at 44, and some of this light reflected by coating 24 passes through LCD 40.

In a final step 310, at least one mirror is used to reflect light passed by the liquid crystal display toward a windshield of the motor vehicle such that the light is reflected by the windshield and is visible to the human driver as a virtual image. For example, a light field 26 passed by LCD 40, after being first reflected by mirror 20, may be reflected by mirror 22 and then by windshield 16 such that the reflection is visible to a driver 28 as a virtual image 30.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. A head up display system for presenting a virtual image to a human driver of a motor vehicle, the system comprising:
a picture generation unit including:
a printed circuit board having at least one light emitting device configured to emit light from a surface of the printed circuit board, the surface having an optically reflective coating; and
a liquid crystal display configured to receive the emitted light and reflect a portion of the received emitted light back to the printed circuit board, wherein the optically reflective coating of the printed circuit board is configured to reflect the light reflected by the liquid crystal display back to the liquid crystal display; and
at least one mirror configured to reflect light passed by the liquid crystal display toward a windshield of the motor vehicle such that the light is reflected by the windshield and is visible to the human driver as the virtual image.

2. The system of claim 1 wherein the optically reflective coating is configured to reflect over 90 percent of the light reflected by the liquid crystal display back to the liquid crystal display.

3. The system of claim 2 wherein the optically reflective coating comprises an aluminum coating.

4. The system of claim 1 wherein the picture generation unit includes a first lens disposed between the printed circuit board and the liquid crystal display.

5. The system of claim 4 wherein the picture generation unit includes a collimating lens disposed between the first lens and the liquid crystal display.

6. The system of claim 5 wherein the printed circuit board, the collimating lens, the first lens, and the liquid crystal display are substantially parallel to each other.

7. The system of claim 1 wherein the at least one mirror comprises a plurality of mirrors.

8. A method for presenting a virtual image to a human driver of a motor vehicle, the method comprising:
providing a printed circuit board including a surface having an optically reflective coating;
emitting light from the surface of the printed circuit board;
using a liquid crystal display to receive the emitted light and reflect a portion of the received emitted light back to the printed circuit board;
using the optically reflective coating of the printed circuit board to reflect the light reflected by the liquid crystal display back to the liquid crystal display; and
using at least one mirror to reflect light passed by the liquid crystal display toward a windshield of the motor vehicle such that the light is reflected by the windshield and is visible to the human driver as the virtual image.

9. The method of claim 8 wherein the optically reflective coating reflects over 90 percent of the light reflected by the liquid crystal display back to the liquid crystal display.

10. The method of claim 9 wherein the optically reflective coating comprises an aluminum coating.

11. The method of claim 8 further comprising providing a first lens between the printed circuit board and the liquid crystal display.

12. The method of claim 11 further comprising providing a collimating lens disposed between the first lens and the liquid crystal display.

13. The method of claim 12 wherein the printed circuit board, the collimating lens, the first lens, and the liquid crystal display are substantially parallel to each other.

14. The method of claim 8 wherein the at least one mirror comprises a plurality of mirrors.

15. A picture generation unit for a head up display system that presents a virtual image to a human driver of a motor vehicle, the picture generation unit comprising:
a printed circuit board including at least one light emitting device configured to emit light from a surface of the printed circuit board, the surface having an optically reflective aluminum coating; and
a liquid crystal display configured to receive the emitted light and reflect a portion of the received emitted light back to the printed circuit board, wherein the optically reflective aluminum coating of the printed circuit board is configured to reflect the light reflected by the liquid crystal display back to the liquid crystal display, wherein light passing through the liquid crystal display is reflected so as to be visible to the human driver as the virtual image.

16. The picture generation unit of claim 15 wherein the optically reflective aluminum coating is configured to reflect over 90 percent of the light reflected by the liquid crystal display back to the liquid crystal display.

17. The picture generation unit of claim 15 wherein the picture generation unit includes a first lens disposed between the printed circuit board and the liquid crystal display.

18. The picture generation unit of claim 17 wherein the picture generation unit includes a collimating lens disposed between the first lens and the liquid crystal display.

19. The picture generation unit of claim 18 wherein the printed circuit board, the collimating lens, the first lens, and the liquid crystal display are substantially parallel to each other.

20. The picture generation unit of claim 15 wherein the surface of the printed circuit board is substantially planar.
